(19) United States
(12) Patent Application Publication
(10) Pub. No.: US 2001/0046646 A1
(43) Pub. Date: Nov. 29, 2001

(54) Stencil mask and method for manufacturing same

(75) Inventor: Fumihiro Koba, Tokyo (JP)

Correspondence Address: Norman P. Soloway, HAYES, SOLOWAY, HENNESSEY, GROSSMAN & HAGE, P.C., 175 Canal Street, Manchester, NH, 03101, US

(73) Assignee: NEC Corporation

(21) Appl. No.: 09/859,634

(22) Filed: May 17, 2001

(30) Foreign Application Priority Data
May 18, 2000 (JP) 2000-146337

(51) Int. Cl. G03F 9/00

(52) U.S. Cl. 430/308; 430/5

(57) ABSTRACT

A stencil mask has a mask layer having an aperture part with either one or a plurality of apertures, a support part supporting the mask part formed by parts other the aperture parts, and a silicon oxide film layer, disposed between the support part and the mask layer, this silicon oxide film layer including a metal.

### BACKGROUND OF THE INVENTION

1. Field of the Invention

The present invention relates to a stencil mask and a to a method for manufacturing a stencil mask, and more particularly it relates to a stencil mask and method for manufacturing a stencil mask having a fine mask pattern, with good precision, no dependency on temperature, and a good transfer accuracy.

2. Description of the Related Art

In the past, in the case of forming a prescribed pattern using an electron beam and using optics such as an electron lens or the like to expose a wafer or the like with a prescribed reduction ratio, so as to form a prescribed pattern on a wafer, the use of a stencil mask is well known.

For example, FIG. 4 shows a cross-sectional view of the process steps, illustrating an example of a method for manufacturing a stencil mask in the past. First, as shown in FIG. 4(a), a silicon oxide film 42 is formed on the upper surface of a 200-mm-diameter silicon wafer (support side silicon substrate), using CVD (chemical vapor deposition).

Next, as shown in FIG. 4(b), the a surface-side silicon substrate 43 onto which a mask is to be formed is attached, and polished to a thickness of approximately 2 μm using CMP (chemical mechanical polishing).

Next, as shown in FIG. 4(c), resist is spin-coated onto the surface-side silicon substrate 43, and electron beam lithography is used to form a resist pattern, this resist being then used as a mask in performing dry etching of the silicon substrate 43 at the resist aperture parts, thereby patterning the surface-side silicon substrate 43.

Finally, as shown in FIG. 4(d), a mask is formed with apertures at only prescribed parts of the rear surface of the support-side silicon substrate 41, and silicon wet etching is performed (this being referred to hereinafter as back etching).

Back etching of the support-side silicon substrate 41 is done using the silicon oxide film 42 as an etch stopper until the surface-side silicon oxide film 42 is exposed, after which the surface-side silicon substrate 43 is used as an etch stopper to back etch the silicon oxide film 42 until the surface-side silicon substrate 43 is exposed, thereby forming the stencil mask.

An important element of a silicon stencil mask for electron beam lithography to which the present invention is to be applied is achieving a high transfer accuracy.

However, in a method of manufacturing a stencil mask of the past, although the silicon oxide film is removed from the pattern region, because the support region silicon oxide film ultimately remains, stress develops because of the difference in coefficients of thermal expansion between the silicon substrate and the silicon oxide film, thereby causing a reduction in the transfer accuracy.

Additionally, because the thermal conductivity of the silicon oxide film is low, the temperature of the overall stencil mask in non-uniform, and in local parts thereof where the temperature is elevated, stress develops, thereby worsening the transfer accuracy.

Additionally, because of the low electrical conductivity of the silicon oxide film, localized charging up occurs, thereby causing a change in the electron beam axis, leading to the problem of worsened transfer accuracy.

For example, in the Japanese laid-open patent application publication S62-089053, there is a disclosure with regard to a method for forming a photomask, wherein ion implantation is done over the entire surface of a mask substrate made of silica glass, so as to implant sodium ions and then a chrome film is patterned on this surface, so as to form a photomask with good immunity to thermal stress and high transfer accuracy.

This technology is somewhat effective in relieving thermal stress and preventing charging up.

However, in this invention metal ion implantation is done over the entire substrate surface made of silica glass, and if the invention is applied as is to a stencil mask, not only the support region, but also the pattern region is subjected to ion implantation, resulting in crystal flaws in the pattern region silicon substrate and silicon oxide film. These crystal flaws cause a deterioration of the process accuracy in dry etching and wet etching.

Additionally, because of crystal flaws caused by metal ions existing in the pattern region silicon oxide film or silicon substrate, there is a reduction in the accuracy of the stopper in back etching, making it impossible to manufacture a precision mask pattern.

In the Japanese laid-open patent application publication S62-31853, there is disclosure with regard to a mask made of silica glass, in which ion implantation is done to the surface thereof, so as to lower the surface resistivity thereof.

However, this prior art is a mask that is directly formed on a glass substrate, so that not only is there no disclosure of the mask of the present invention, but also the purpose of this prior art is indicated by example as that of implanting chrome ions into the entire surface of the silica substrate for the purpose of discharging a charge that develops on the silicon substrate, there being absolutely no language therein with regard to a the configuration of a stencil mask such as in the present invention.

In Japanese patent 2979631, there is language disclosing a method for forming a stencil mask, wherein boron is implanted into a silicon substrate, after which tungsten is deposited onto the boron layer, the boron layer and tungsten layer being then etched to achieve a prescribed aperture pattern, the boron layer being further covered by a tungsten layer to form the stencil mask.

In this prior art example, however, because of the large difference in the etching rates between silicon and boron-doped silicon, when performing etching of the silicon layer, the boron-doped silicon cannot function sufficiently as an etching stopper, the result being that it is difficult form a high-precision mask pattern for stencil masks, which are exhibiting shrinking feature size, in addition to the problem that the boron-doped silicon layer has many crystal flaws, which make it impossible to form a precision pattern for use in forming the mask pattern.

Additionally, because the tungsten in the tungsten layer in this example of prior art generally has a large grain size, large spaces formed between grains therein present the problem of a lowering of the accuracy of processing the mask pattern when etching the tungsten layer.

Additionally, in this example of prior art there is a laminate formed, in which the boron-doped silicon layer and tungsten layer are in mutual contact, because of the difference in thermal coefficients of expansion between the boron-doped silicon layer and the tungsten layer, because of the effect of heat generated in manufacturing and use, stress develops between these two elements, thereby causing the problem of a reduction in the accuracy of mask positioning. This problem becomes a serious problem that has gained attention as the feature sizes of stencil masks shrinks and the thickness thereof is reduced.

In this prior art example, however, there is absolutely no disclosure of technology to solve this problem.

Accordingly, it is an object of the present invention to solve the above-described problems in the prior art, by providing a stencil mask and method for manufacturing a stencil mask applicable to fine, thin stencil masks as well, which not only maintains a prescribed strength, but also effectively prevents deformation caused by thermal stress, thereby providing a stencil mask with a precising processed pattern.

### SUMMARY OF THE INVENTION

To achieve the above-noted objects, the present invention adopts the following basic technical constitution.

Specifically, a first aspect of the present invention is a stencil mask having a mask layer with an aperture part, a support part supporting the mask layer in a part other than the aperture part, and a silicon oxide film layer, which includes a metal, and provided between the mask layer and the support part.

A second aspect of the present invention is a method for manufacturing a stencil mask, this method minimally having a step of forming a laminate of a silicon film layer, onto which is formed a support part, and a silicon oxide film layer which forms a part of the support part,a step of forming a resist layer on the silicon oxide film layer and patterning same so as to achieve a prescribed pattern, a step of performing metal ion implantation into the silicon oxide film layer, using the patterned resist layer as a mask, a step of performing patterning of the silicone film layer formed on the silicon oxide film layer to be used for a mask, and forming an aperture part in the silicon oxide film layer disposed on the silicon oxide film layer not subjected to metal ion implantation, through which an electron beam can pass, and a step of performing etching the silicone film layer on which the support part is formed, from a main surface on which the silicon oxide film layer is not formed thereon, and removing the silicon oxide film layer that does not include the silicon film layer and the metal, and other than the part that makes up the support part.

A stencil mask and method for manufacturing a stencil mask according to the present invention adopts the above-described technical constitution, thereby providing a stencil mask applicable to even fine, thin stencil masks, which not only maintains a prescribed accuracy, but also effectively prevents deformation caused by thermal stress, thereby providing a stencil mask with a precising processed pattern.

### BRIEF DESCRIPTION OF THE DRAWINGS

FIG. 1 is a cross-sectional view showing the general configuration of an example of a stencil mask according to the present invention.

FIG. 2 is a drawing showing the flow of processes in an example of a method for manufacturing a stencil mask according to the present invention.

FIG. 3 is a drawing showing the flow of processes in another example of a method for manufacturing a stencil mask according to the present invention.

FIG. 4 is a drawing showing the flow of processes an example of a method for manufacturing a stencil mask in the past.

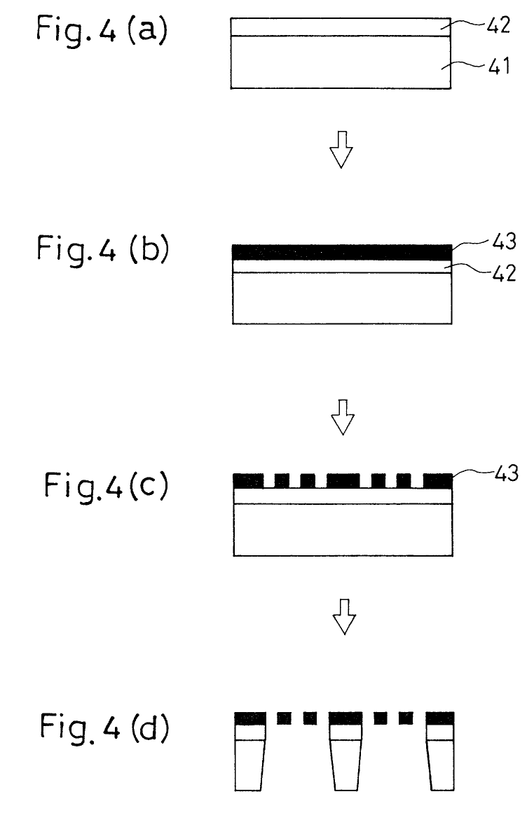

### DETAILED DESCRIPTION OF THE PREFERRED EMBODIMENTS

Embodiments of the a stencil mask and a method for manufacturing a stencil mask according to the present invention are described in detail below, with references made to relevant accompanying drawings.

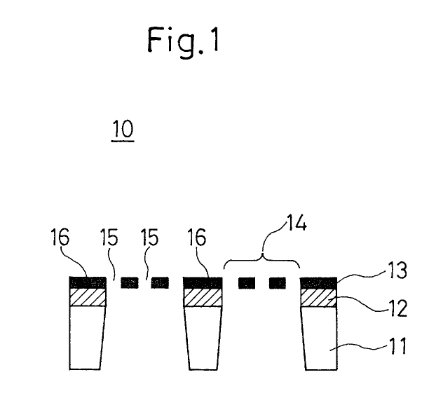

Specifically, FIG. 1 is a cross-sectional view showing the general configuration of an example of a stencil mask according to the present invention, this drawing showing a stencil mask 10 having a mask layer 13 having an aperture part 14 that has one or a plurality of apertures 15, a support part 11 supporting the mask layer 13 consisting portion 6 other than the aperture part 14, and a silicon oxide film layer 12, which includes a metal, and provided between the mask layer 13 and the support part 11.

In the stencil mask 10 according to the present invention, it is desirable that the support part 11 be formed by a silicon film layer.

It is further desirable that the mask layer 13 of the present invention be formed by a silicon film layer.

It is preferable that the silicon oxide film layer 12, which includes a metal and which is used in the stencil mask 10 of the present invention, includes at least one metal atom, selected from a group consisting of, for example, phosphorus, boron, tungsten, and the like.

It will be understood, of course, that it is possible to use a metal other than the ones noted above.

A stencil mask 10 according to the present invention, as noted above, is stencil mask for use in electron beam lithography, and by using a known means to implant ions of a metal atom of, for example, phosphorus, boron or the like in only the silicon oxide film layer 12 between the supports 11 and mask layer 13 of the stencil mask 10, it is possible to use an SOI (silicon on insulator) wafer, for example, to manufacture the stencil mask.

More specifically, the stencil mask 10 according to the present invention has a configuration in which there is a silicon oxide film 12 between the front surface-side silicon substrate 13 and the support-side silicon substrate 11, with metal ions of atoms of phosphorus, boron, or the like included in the silicon oxide film 12, which corresponds to region of the supports 11 of the stencil mask 10.

In a stencil mask 10 according to the present invention, therefore, because of the existence of metal atoms within this silicon oxide film 12, the thermal conductivity of the silicon oxide film 12 is made large, thereby enabling suppression of a local temperature rise in the stencil mask, and enabling prevention of deformation of the stencil mask caused by thermal stress.

In the stencil mask 10 according to the present invention, it is possible with a fine, thin tungsten layer, to fabricate a stencil mask having the prescribed strength and immunity to stress deformation.

That is, in the stencil mask 10, since the smaller the thickness becomes, the greater the tendency is for the stencil mask 10 to deform, it would be necessary to make countermeasures to accommodate this problem. In the present invention, however, as noted above, by implanting metal ions into the silicon oxide film layer 12, it is possible to solved this problem.

Metal atoms such as phosphorus or boron atoms or the like impart viscosity to the silicon oxide film 12, which absorbs stress caused by a difference in coefficients of thermal expansion between the silicon oxide film 12 and the surface-side silicon substrate 13, enabling prevention of stencil mask deformation.

In the same manner, stress developing due to the difference in coefficients of thermal expansion between the silicon oxide film 12 and the support-side silicon substrate 11 are absorbs, thereby enabling prevention of stencil mask deformation.

Additionally, in the stencil mask 10 according to the present invention, by virtue of the existence of metal atoms, the electrical conductivity of the silicon oxide film 12 is made large, thereby enabling prevention of localized charging up.

Therefore, when the light axis of a laser beam passing through the stencil mask 10 passes through an aperture 15 of the stencil mask 10, deflection of the axis by an electrical charge of the silicon oxide film 12 is prevented, resulting in transfer of a highly precise mask pattern.

Furthermore, the metal atoms in the present invention exist only in the silicon oxide film 12 in the support region of the stencil mask 10, and do not exist in the parts of the silicon oxide film 12 corresponding to the aperture part 14 which is the pattern region.

Therefore crystal flaws occurring because of the existence of the metal ions themselves or because of the metal ion implantation do not cause a deterioration of the pattern processing accuracy.

Additionally, because there are no crystal flaws occurring in the silicon oxide film 12 part corresponding to the pattern region caused by the metal ion or metal ion implantation, there is no deterioration of the function of acting as a stopper for the silicon oxide film during the back etching process.

That is, because there is no intermixing of a metal in the part of the silicon oxide film layer 12 corresponding to the aperture part 14, because there is the required difference in the etching rate with respect to the silicon layer 11, in order to leave the support part 11, when performing two-stage etching processing of the silicon layer 11 from the surface on which the silicon oxide film layer 12 is not provided, in the first etching process it is possible to reliably stop the etching of the silicon layer 11 at the lower surface of the silicon oxide film layer 12, and in the second etching process it is possible to stop the etching of the silicon oxide film layer 12 at the surface of the surface-side silicon substrate 13 that has the aperture part 14, and as a result the patterning of the stencil mask 1 can be made extremely fine.

A specific example of a method for manufacturing a stencil mask according to the present invention is described below, with reference made to associated flowcharts.

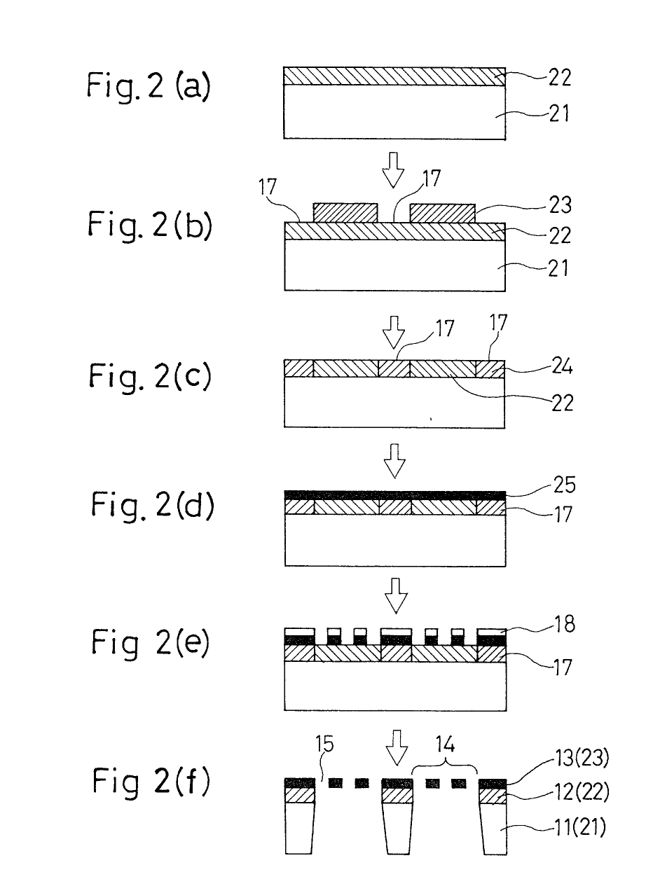

First, as shown in FIG. 2(a), thermal oxidation or CVD (chemical vapor deposition) is used to form a silicon oxide film 22 having a thickness of 1 μm on the surface of a silicon (Si) wafer (support-side silicon substrate) having a diameter of 200 mm.

Next, as shown in FIG. 2(b), resist is spin-coated onto the surface of the silicon oxide film 22 on the support-side silicon substrate 21, and electron beam lithography is used to form a resist pattern 23.

In this method, the resist pattern 23 is patterned so as to create apertures in the part that remains 17 afterward in the silicon oxide film layer 12 as supports.

Next, as shown in FIG. 2(c), the resist pattern 23 is used as a mask to implant metal ions such as phosphor ions, tungsten, boron or the like into the silicon oxide film 22, and after formation of the metal ion implanted region 24, the resist 23 is removed.

If the metal ions that are implanted as noted above exist within the silicon oxide film, it is desirable to use a metal ion that has a higher electrical conductivity and thermal conductivity than the silicon oxide film.

Next, as shown in FIG. 2(d), on the side of the silicon oxide film layer 22 opposite from the silicon substrate 21 side, a surface-side silicon substrate 25 is formed, onto which the mask pattern is to be formed, this being polished using CMP (chemical mechanical polishing) to a thickness of approximately 2 μm.

Next, as shown in FIG. 2(e), resist 18 is spin-coated onto the surface-side silicon substrate 25, and electron beam lithography is used to form a resist pattern, this resist pattern being used as a mask to perform drying etching of the silicon substrate 25 in the resist aperture parts, thereby patterning the surface-side silicon substrate 25.

Finally, as shown in FIG. 2(f), a mask is formed with apertures only in a prescribed part on the reverse surface side of the support-side silicon substrate 21, and silicon wet etching is then performed (this being referred to as back etching).

Back etching is done using the silicon oxide film 22 as an etch stopper until the silicon oxide film 22 is exposed, after which the surface-side silicon substrate 25 is used as an etch stopper to back etch until the surface-side silicon substrate 25 is exposed, thereby forming the stencil mask.

This back etching is not restricted to wet etching, and can alternatively be done by dry etching.

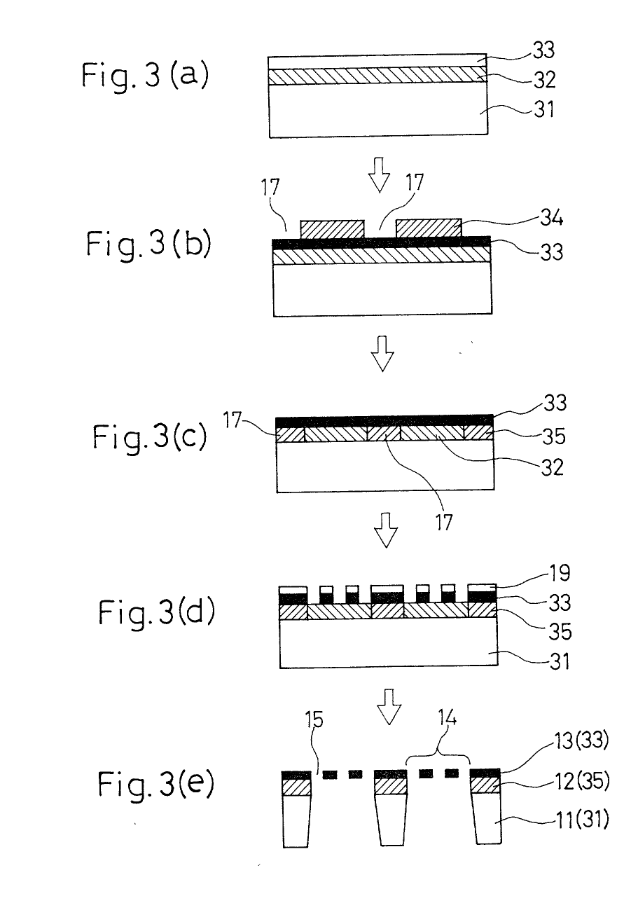

Another embodiment of a method for manufacturing a stencil mask 10 according to the present invention is described below, referring to FIG. 3, which shows the flow of process steps in this method.

First, as shown in FIG. 3(a), a SOI (silicon on insulator) wafer having a diameter of 200 mm is prepared.

The method for manufacturing the SOI wafer in this embodiment can be either the method of joining the two layers, or various manufacturing methods such as SIMOX.

As shown in FIG. 3(a), the SOI is formed by a support-side silicon substrate 31, a silicon oxide film 32, and a surface-side silicon substrate 33.

Next, as shown in FIG. 3(b), resist 34 is spin-coated onto the surface-side silicon substrate 33, and electron beam lithography is used to create a resist pattern 34. The resist pattern 34 in this case is patterned so as to have apertures in the aperture part that will remain later as the supports.

Next, as shown in FIG. 3(c), the resist pattern 34 is used as a mask to perform ion implantation of phosphorus or boron ions, or implantation of metal ions such as tungsten, thereby forming a metal ion implanted region 35, after which the resist is removed.

If the metal ions that are implanted as noted above exist within the silicon oxide film, it is desirable to use a metal ion that has a higher electrical conductivity and thermal conductivity than the silicon oxide film.

Next, as shown in FIG. 3(d), resist 19 is spin-coated onto the surface-side silicon substrate 33, and electron beam lithography is used to form a resist pattern, this resist 19 being then used to perform dry etching of the silicon substrate 33 of the aperture parts, so as to pattern the surface-side silicon substrate 33.

Finally, as shown in FIG. 3(e), apertures are formed in only a prescribed part of the rear surface of the support-side silicon substrate 31, so as to form a mask, and silicon wet etching (back etching) is performed.

Back etching of the silicon oxide film 32 is done using the silicon oxide film 32 as an etching stopper until the silicon oxide film 32 is exposed, after which the surface-side silicon substrate 33 is used as an etching stopper to perform back etching until the surface-side silicon substrate 33 is exposed, thereby forming the stencil mask.

This back etching is not restricted to wet etching, and can alternatively be done by dry etching.

That is, whereas in the above-described embodiment of the present invention, patterning is first done of the surface-side silicon substrate 33, after which batch etching is done from the rear side of the support-side silicon substrate 31, it is alternately possible to achieve the effect of the present invention by first performing back etching of the support-side silicon substrate 31, and then performing back etching to pattern the rear-surface silicon substrate.

Additionally, in yet another method for manufacturing a stencil mask according to the present invention, in contrast to the above-described embodiment, in which the present invention is applied to a silicon stencil mask for electron beam lithography, the present invention is applied to X-ray lithography or ion-beam lithography.

As is clear from the above-noted embodiments of a method for manufacturing a stencil mask 10, a method for manufacturing a stencil mask according to the present invention that encompasses the above-described embodiments basically minimally has a step of forming a laminate of a silicon film layer, onto which is formed a support part, and a silicon oxide film layer which forms part of the support part, a step of forming a resist layer on the silicon oxide film layer and patterning to achieve a prescribed pattern, a step of using the patterned resist film as a mask to perform metal ion implantation of the silicon oxide film layer, a step of performing patterning of the silicon oxide film layer to form a mask, and forming an aperture part in the silicon oxide film layer disposed on the silicon oxide film layer not subjected to metal ion implantation, through which an electron pass, and a step of performing etching from the main surface part on which the silicon oxide film layer is not formed on the silicon film layer on which the support part is formed, and removing the silicon oxide film layer that does not include the silicon film layer and this metal, other than the part that makes up the support part.

In a method for manufacturing a stencil mask according to the present invention, it is desirable that the metal implanted in the silicon oxide film layer be at least one metal atom selected from the group consisting of phosphorus, boron, and tungsten.

It is further desirable that the silicon film layer for forming the mask that is provided on the silicon oxide film layer be formed on the silicon oxide film layer before the process step of performing ion implantation of the silicon oxide film layer.

It is also desirable in a method for manufacturing a stencil mask according to the present invention that the silicon layer for forming the mask, which is provided on the silicon oxide film layer, be formed on the silicon oxide film layer after the process step of implanting metal ions into the silicon oxide film layer.

In the same manner, in a method for manufacturing a stencil mask according to the present invention, it is preferable in the process step of performing metal ion implantation into the silicon oxide film layer, that the metal ions be implanted in locations in the silicon oxide film layer that is in opposition to the parts of the silicon layer in which the support parts are formed.

It is also preferable in a method for manufacturing a stencil mask according to the present invention that the etching in the silicon film layer on which the support parts are formed is done in two etching steps.

By adopting the above-described technical constitution, a stencil mask and method for manufacturing a stencil mask according to the present invention improve on the drawbacks associated with the prior art, and even in the case of a fine, thin stencil mask, not only maintain the prescribed strength and prevent deformation caused by thermal strength, but also achieves a stencil mask and method for manufacturing a stencil mask having a highly precise pattern.

What is claimed is:

1. A stencil mask comprising:
a mask layer comprising an aperture part;
a support part supporting said mask layer other than said aperture part; and
a silicon oxide film layer disposed between said mask layer and said support part, which including a metal.

2. A stencil mask according to claim 1, wherein said support part is formed by a silicon film layer.

3. A stencil mask according to claim 1, wherein said mask layer is formed by a silicon film layer.

4. A stencil mask according to claim 1, wherein said silicon oxide film layer including a metal includes at least one metal atom selected from a group consisting of phosphorus atoms, boron atoms, and tungsten atoms.

5. A method for manufacturing a stencil mask, comprising steps of:
forming a laminate of a silicon film layer, onto which is formed a support part, and a silicon oxide film layer which forms a part of said support part;
forming a resist layer on said silicon oxide film layer and patterning same so as to achieve a prescribed pattern;
using said patterned resist layer as a mask, performing metal ion implantation into said silicon oxide film layer;
performing patterning of said silicone film layer formed on said silicon oxide film layer to be used for a mask, and forming an aperture part in said silicon oxide film layer disposed on said silicon oxide film layer not subjected to metal ion implantation, through which an electron beam can pass; and
performing etching said silicone film layer on which said support part is formed, from a main surface on which said silicon oxide film layer is not formed thereon, and removing said silicon oxide film layer that does not include said silicon film layer and said metal, and other than said part that makes up said support part.

6. A method for manufacturing a stencil mask according to claim 5, wherein said metal implanted into said silicon oxide film layer is at least one metal atom selected from a group consisting of phosphorus atoms, boron atoms, and tungsten atoms.

7. A method for manufacturing a stencil mask according to claim 5, wherein said silicon layer for mask formation provided on said silicon oxide film layer is formed on said silicon oxide film layer before said step of implanting a metal ion into said silicon oxide film layer.

8. A method for manufacturing a stencil mask according to claim 5, wherein said silicon layer for mask formation provided on said silicon oxide film layer is formed on said silicon oxide film layer after said step of implanting a metal ion into said silicon oxide film layer.

9. A method for manufacturing a stencil mask according to claim 5, wherein in said step of implanting a metal ion into said silicon oxide film layer, said metal ion is implanted at a location of said silicon oxide film layer opposing a part of said silicon layer on which said support part is formed.

10. A method for manufacturing a stencil mask according to claim 5, wherein etching in said silicon layer on which said support part is formed is performed in two etching process steps.
